(19) United States
(12) Patent Application Publication
(10) Pub. No.: US 2014/0146504 A1
(43) Pub. Date: May 29, 2014

(54) CIRCUIT BOARD, PACKAGE STRUCTURE AND METHOD FOR MANUFACTURING SAME

(71) Applicant: Zhen Ding Technology Co., Ltd., Taoyuan (TW)

(72) Inventor: WEN-HUNG HU, Taoyuan (TW)

(73) Assignee: ZHEN DING TECHNOLOGY CO., LTD., Taoyuan (TW)

(21) Appl. No.: 14/092,965

(22) Filed: Nov. 28, 2013

(30) Foreign Application Priority Data
Nov. 28, 2012 (CN) 2012104940055

(51) Int. Cl. H05K 1/11; H05K 3/00

(52) U.S. Cl. CPC H05K 1/111; H05K 3/007
USPC 361/767; 174/261; 174/266; 156/182

(57) ABSTRACT

A circuit board includes at least one core substrate, at least one insulating layer and at least one dielectric sheet. An opening is defined in the insulating layer corresponding to the core substrate. An area of cross-section of the opening is larger than that of the core substrate. The core substrate is received in the opening. The dielectric sheet is positioned on one side surface of the core substrate and the insulating layer. A cavity is defined in the circuit board. A number of pads of the core substrate are exposed via the cavity. The present disclosure also provides a method for manufacturing the circuit board and package structure.

### BACKGROUND

1. Technical Field

The present disclosure relates to a method for manufacturing a circuit board, and particularly to a circuit board, and method for manufacturing the package structure.

2. Description of Related Art

Printed circuit boards are wildly used because of high density of assembling. The applications of printed circuit boards can reference, for example, Takahashi, A. Ooki, N. Nagai, A. Akahoshi, H. Mukoh, A. Wajima, M. Res. Lab, High density multilayer printed circuit board for HITAC M-880, IEEE Trans. On Components, Packaging, and Manufacturing Technology, 1992, 15 (4): 1418-1425.

The solder pads of the outer conductive wire of a common circuit will be exposed on the same side of circuit board and the exposed solder pads are on the same surface. When chip is mounted on the exposed solder pads, the solder pads are below the chip, therefore the height of the circuit board with the chip is increased and as such the size of the circuit board has been enlarged.

### BRIEF DESCRIPTION OF THE DRAWINGS

FIG. 1 is a cross-section view of a core substrate according to an embodiment of the present disclosure.

FIG. 2 is a cross-section view of a first insulating layer according to an embodiment of the present disclosure.

FIG. 3 is a cross-section view of a second insulating layer according to an embodiment of the present disclosure.

FIG. 4 is a cross-section view of a carrier according to an embodiment of present disclosure.

FIG. 5 is a cross-section view of a first dielectric sheet and a second dielectric sheet according to an embodiment of the present disclosure.

FIG. 6 is a cross-section view of the stacking structure of the combined core substrate, the conductive substrate, the carrier and the dielectric sheet.

FIG. 7 is a cross-section view of two circuit bases.

FIG. 8 is a cross-section view of separating the two circuit bases and the carrier.

FIG. 9 is a cross-section view of defining voids and blind holes of the circuit base.

FIG. 10 is a cross-section view of forming a first outer wiring layer and a second outer wiring layer on two opposite sides of the circuit base.

FIG. 11 is a cross-section view of eliminating the protective layer of FIG. 10.

FIG. 12 is a cross-section view of the circuit board according to the present disclosure.

FIG. 13 is a cross-section view of the package structure according to the present disclosure.

### DETAILED DESCRIPTION

In view of above-mentioned problems, it is necessary to provide a circuit board, package structure and manufacturing method for the same. As such, the obtained circuit board receives a chip and forms a miniaturized sized package structure.

Embodiments will now be described in detail below with reference to the appended figures.

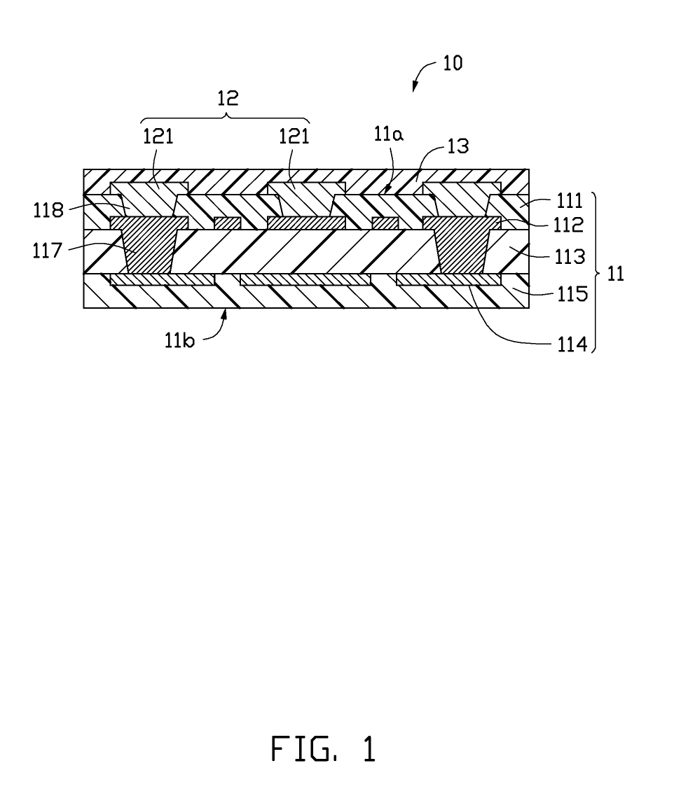

The method for manufacturing a circuit board, comprising steps of: FIG. 1 shows the step of providing a core substrate 10.

The core substrate 10 can be a single side circuit board, double side circuit board or multi layer circuit board, with conductive pattern, the width space of the circuit boards is in the range of 10/10 microns to 20/20 microns. The core substrate 10 comprises a circuit base 11, a first wiring layer 12 and a protective layer 13. A semi-additive process or an additive process can be used to obtain the core substrate.

In this embodiment, the circuit base 11 is a two layer circuit board with two conductive pattern layers. In the illustrated embodiment, the circuit base 11 comprises a first insulating layer 111, a second wiring layer 112, a second insulating layer 113, a third wiring layer 114 and a third insulating layer 115. The second wiring layer 112 and the third wiring layer 114 are positioned on two opposite sides of the second insulating layer 113, and electrically connect with each other through the conductive via 117 defined in the second insulating layer 113. The first insulating layer 111 overlays the second wiring layer 112. The surface of the first insulating layer 111 away from the second insulating layer 113 is the first surface 11a of the circuit base 11. The third insulating layer 115 overlays the third wiring layer 114. The surface of the third insulating layer 115 away from the second insulating layer 113 is the second surface 11b of the circuit base 11.

The first wiring layer 12 is positioned on the surface of the first insulating layer 111 away from the second insulating layer 113, and electrically connects with the third wiring layer 114 through the conductive via 118 defined in the first insulating layer 111. The first wiring layer 12 comprises a plurality of contact pads 121 and a plurality of conductive lines which are not shown in FIG. 1.

The first protective layer 13 covers the first wiring layer 12 to protect the first wiring layer 12 from the damage of the processes following up. The protective layer 13 can be a polymer film, a polypropylene film, a polyethylene film or a polyethylene terephthalate, for example. In this illustrated embodiment, the protective layer 13 is a polyethylene terephthalate. The protective layer 13 can be a strippable film or strippable glue well used in the related art.

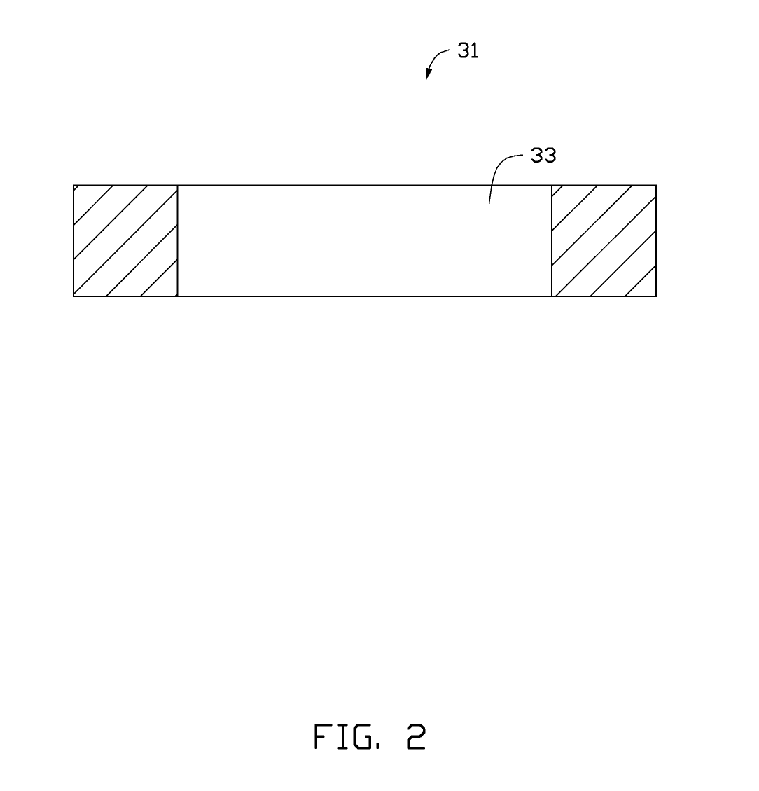

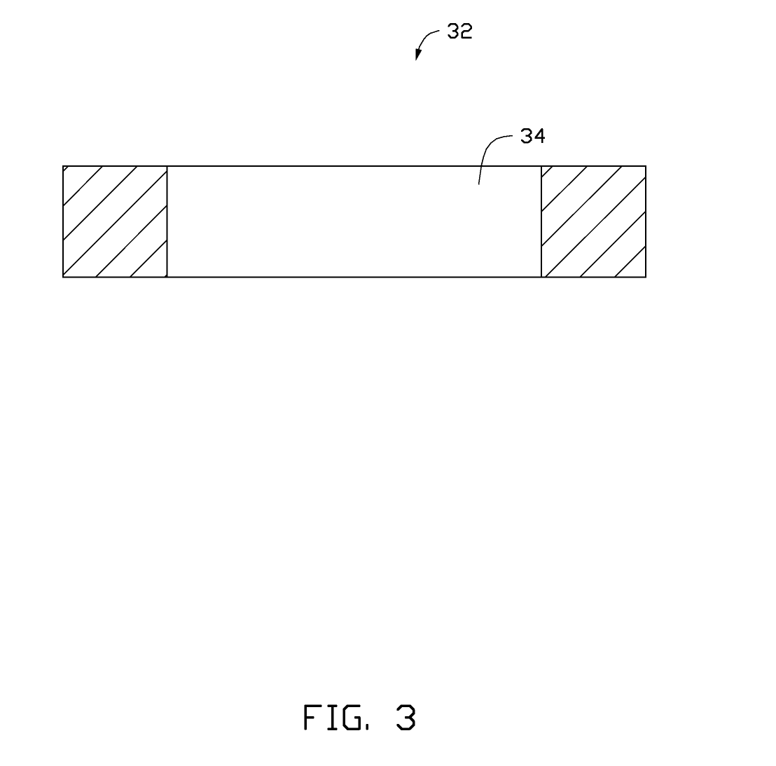

FIG. 2 shows the step of providing a first insulating layer 31; and FIG. 3 shows the step of providing a second insulating layer 32.

The first insulating layer 31 and the second insulating layer 32 are made of insulating materials which can be hard material or flexible material.

First openings 33, which penetrate the first insulating layer 31 through the thickness, are formed in the first insulating layer 31. The first openings 33 are corresponding to the core substrate 10. The shape of the first opening 33 are same as the shape of the core substrate 10, and the area of the cross-section of the first opening 33 is larger than the area of the cross-section of the core substrate 10.

Second openings 34, which penetrate the second insulating layer 32 through the thickness is formed in the second insulating layer 32. The second openings 34 correspond to the core substrate 10. The shape of the second openings 34 are same as the shape of the core substrate 10, and the area of the cross-section of the second opening 34 is larger than the area of the cross-section of the core substrate 10.

In the embodiment, the thickness of the first insulating layer 31 and the second insulating layer are same as the thickness of the core substrate 10.

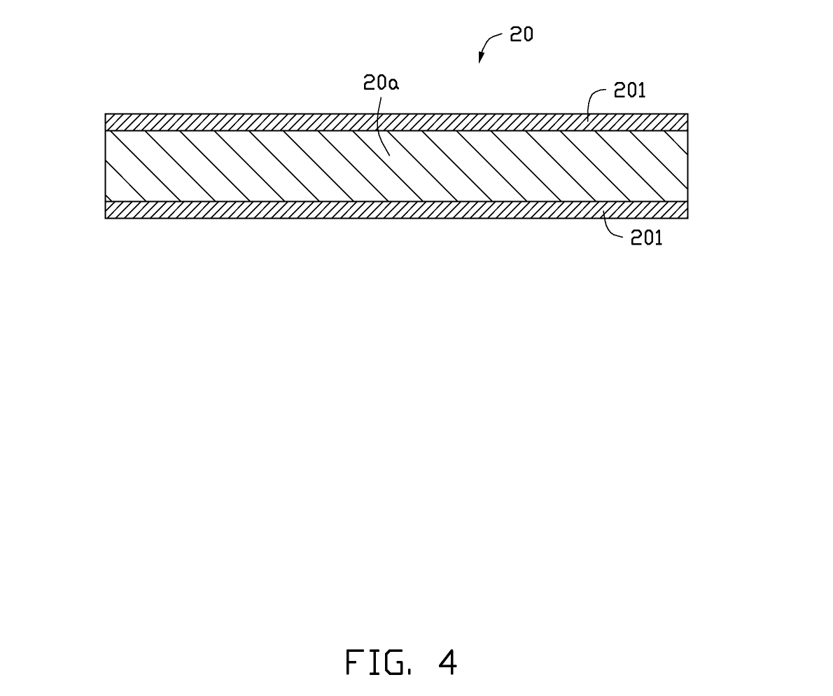

FIG. 4 shows the step of providing a carrier 20. The carrier 20 comprises main body 20a and release films 201 form on two opposite surfaces of the main body 20a. The release films 201 can be polymer film, for example, a polypropylene film, a polyethylene film or a polyethylene terephthalate. In this illustrated embodiment, the release films 201 are polyethylene terephthalate. The release films 201 can be a strippable paper well used in the related art.

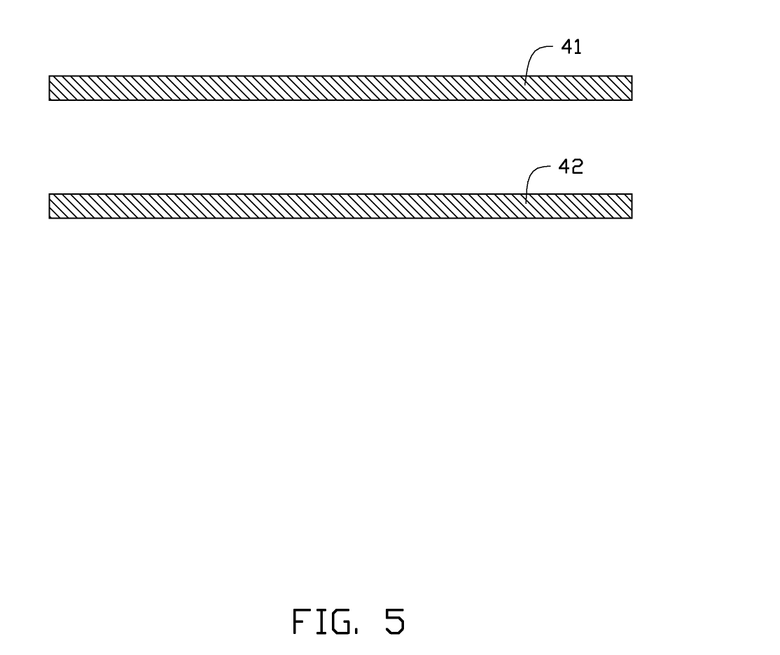

FIG. 5 shows the step of providing a first dielectric sheet 41 and a second dielectric sheet 42. The first dielectric sheet 41 and the second dielectric sheet 42 can be a prepreg sheet well used in the related art.

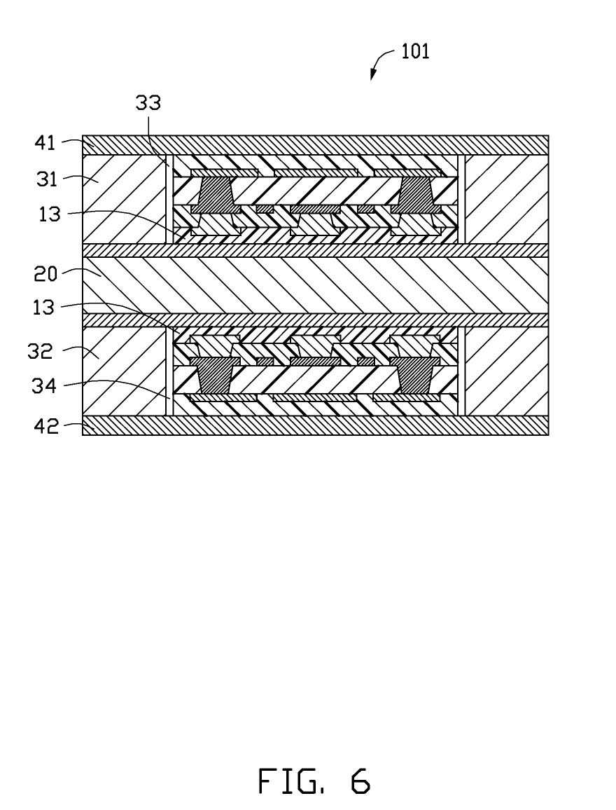

FIG. 6 shows the step of overlaying two core substrates 10 on two opposite sides of the carrier 20. One surface of the protective layer 13 of the core substrate 10 is pasted the surface of the carrier 20. In addition, the first insulating layer 31 and the second insulating layer 32 are positioned on two opposite sides of the carrier 20 positioning one core substrate 10 in the first opening 33 of the first insulating layer 31. As well as positioning the other core substrate 10 in the second opening 34 of the second insulating layer 32. The first dielectric sheet 41 is positioned on the side of one core substrate 10 and the first insulating layer 31 away from the carrier 20. The second dielectric sheet 42 is positioned on the side of the other core substrate 10 and the second insulating layer 32 away from the carrier 20 to form a stacking structure 101.

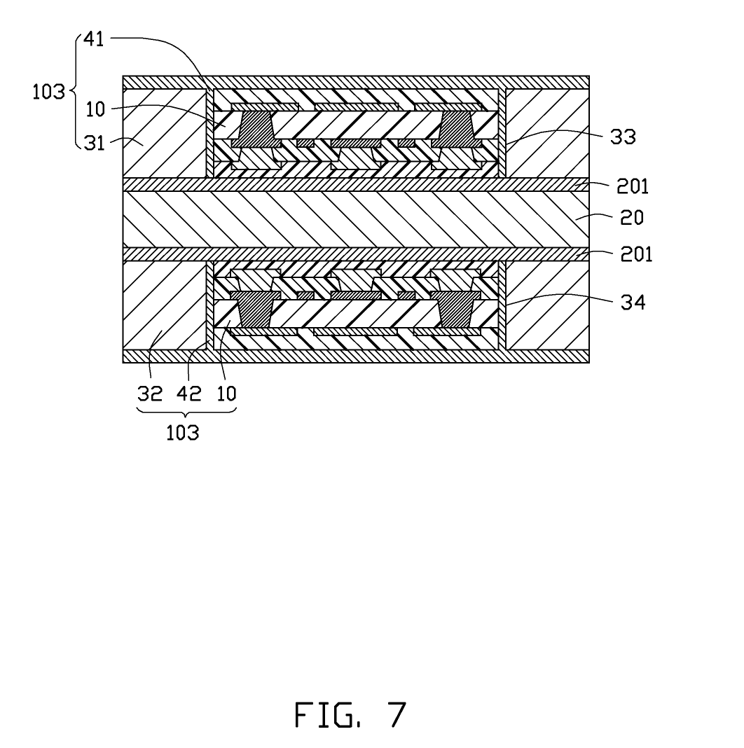

FIG. 7 shows the step of laminating the stacking structure 101 to snake the first dielectric sheet 41 fill the first opening 33, and the gap between the core substrate 10 and the first insulating layer 31 is filled by the first dielectric sheet 41. Therefore the first dielectric sheet 41, the first insulating layer 31 and the core substrate 10 is positioned in the first opening 33 forming a circuit base 103. Similarly, the second dielectric sheet 42 fills into the second opening 34 filling the gap between the core substrate 10 and the second insulating layer 32 with the second dielectric sheet 42. Therefore the second dielectric sheet 42, the second insulating 32 and the core substrate 10 is positioned in the second opening 34 forming the other circuit base 103.

During the laminating process, under high temperature and high pressure, the first dielectric sheet 41 and the second dielectric sheet 42 will turn to fluid. The materials of the first dielectric sheet 41 and the second dielectric sheet 42 can be polyimide, polyethylene terephthalate or polyethylene naphthalate, prepreg or Ajinomoto Build-up film, for example. In the illustrated embodiment, the prepreg and the Ajinomoto Build-up film are used.

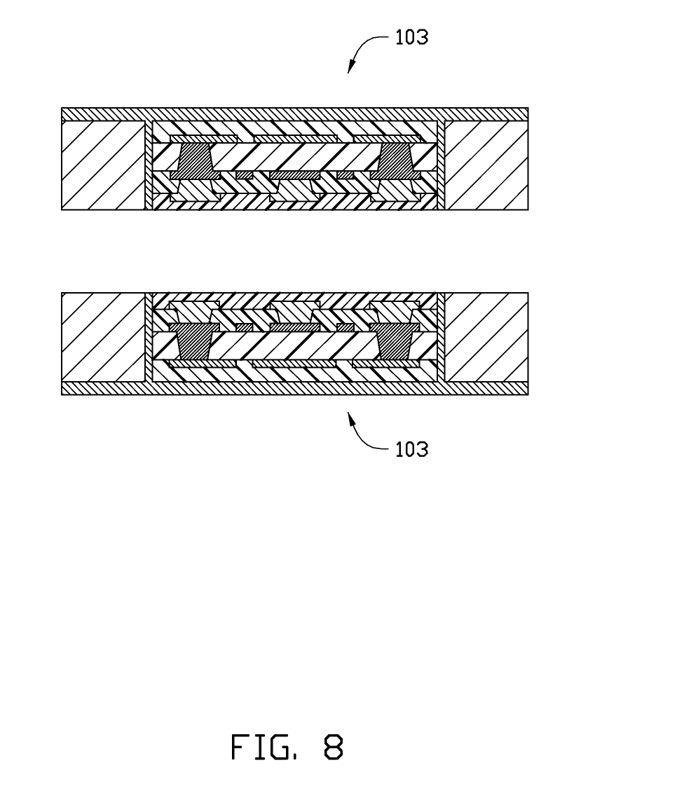

FIG. 8 shows the step of separating the two circuit bases 103 and the carrier 20.

The surface of the carrier 20 has release films 201, therefore the circuit base 103 can be easily separated from the carrier 20.

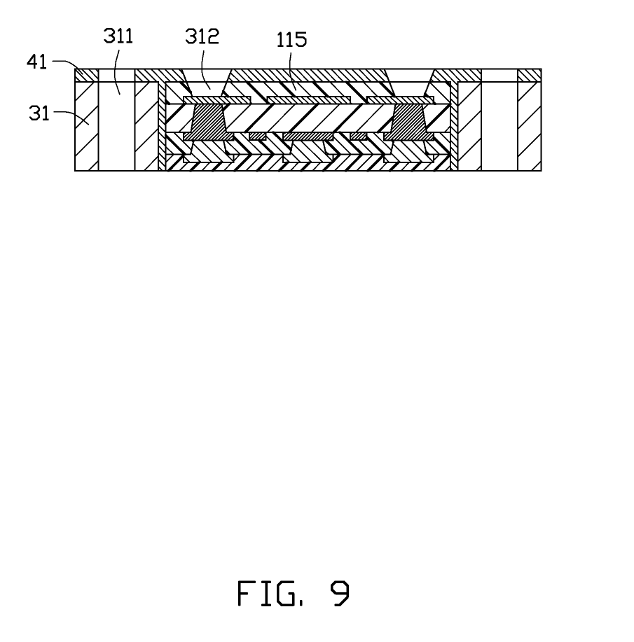

FIG. 9 shows the step of defining at least one void 311 on the first dielectric sheet 41 and the first insulating layer 31 of the circuit base 103. A plurality of blind holes 32 on the first dielectric sheet 41 and the third insulating layer 115 exposes part of the third wiring layer 114.

In the embodiment, the void 311 and the blind holes 312 can be defined by laser ablation. The void 311 is defined through the first insulating sheet 41 and the first insulating layer 31. The void 311 also can be defined by mechanical drilling. The void can be one or more. FIG. 4 shows that when defining the two voids 311, blind holes 312 are defined only in the first dielectric sheet 41 and the third insulating layer 115 and expose part of the third wiring layer 114. The blind hole 312 can be one or more.

In the embodiment, after the process, a step of desmear can be included to eliminate grease smears which are on the inner of the void and the blind hole, therefore the conductivity of the defined conductive via will not be affected by the grease smears when the follow up electroplating is performed.

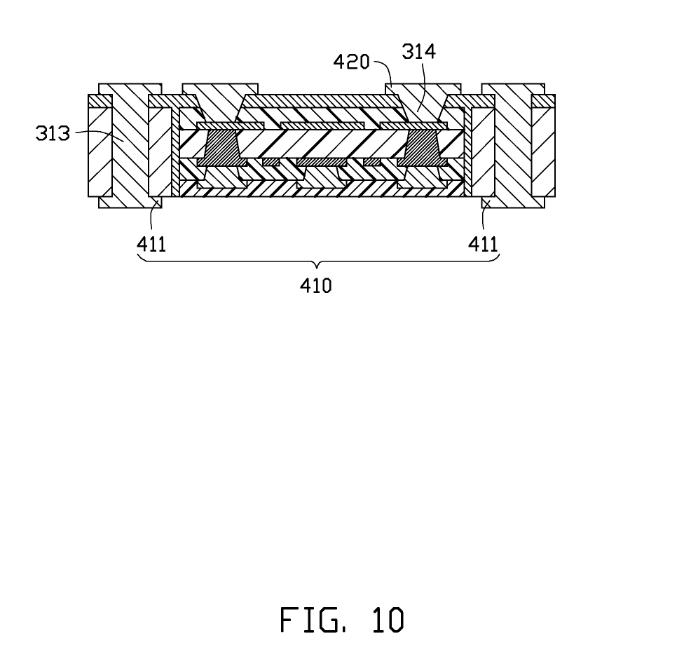

FIG. 10 shows the step of forming a first outer wiring layer 410 on the surface of the first insulating layer 31 and forming a second outer wiring layer 420 on the surface of the dielectric sheet 41. The first outer wiring layer 410 comprises a plurality of second contact pads 411. The second outer wiring layer 420 comprises a plurality of third contact pads which on the surface of the dielectric sheet 41 and a plurality of conductive wires. The range of the width/space of the conductive pattern of the first outer wiring layer 410 and the second outer wiring layer 420 are both between 30/30 micrometers and between 50/50 micrometers. In the illustrate embodiment, the width/space if the first wiring layer is smaller than the width/space of the outer wiring layers.

In the illustrated embodiment, the process can be performed by the following method.

First, forming a first conductive seed layer on the surface of the first insulating layer 31 and the protective layer 13, then forming a second conductive seed layer on the inner side of the voids 311, the inner side of the blind holes 312 and the surface of the first dielectric sheet by electroless copper plating.

Forming the first conductive seed layer and the second conductive seed layer on the surface of the first insulating layer 31, the inner side of the voids 311, the inner side of the blind holes 312 and the surface of the first dielectric sheet 41 can also adopt other methods, for example, blackening or chemical adsorption conductive particles.

After that, forming photosensitivity resist layers on the surface of the first conductive seed layer and the surface of the second conductive seed layer, respectively. Eliminating the part corresponding to the first outer wiring layer 410 to obtain a first photosensitivity resist pattern and eliminating the part corresponding to the second outer wiring layer 420 to obtain a second photosensitivity resist pattern.

Next, forming a first electroplated copper layer on the surface of first conductive seed layer which is exposed via the gap of the first photosensitivity resist pattern, and forming a second electroplated copper layer on the surface of the second conductive seed layer which is exposed via the gap of the second photosensitivity resist pattern.

At last, eliminating the first photosensitivity resist pattern and the second photosensitivity resist pattern by film stripping and eliminating the first conductive seed layer which is covered by the first photosensitivity resist pattern and the second conductive seed layer which is covered by the second photosensitivity resist pattern by micro etching. Therefore, the first conductive seed layer is positioned on the first insulating layer 31 and the first electroplated copper layer is formed on the first conductive seed layer to become a first outer wiring layer 410. The second conductive seed layer is positioned on the surface on the first dielectric sheet 41 and the second electroplated copper layer is formed on the second conductive seed layer to become a second outer wiring layer 420. The second conductive seed layer is positioned in the inner of the voids 311 and second electroplated copper layer formed on the second conductive seed layer to become the conductive via 313 which penetrated the first dielectric sheet 41 and the first insulating layer 31. The second, conductive seed layer is positioned in the inner of the blind hole 312 and the second electroplated copper layer is formed on the second conductive seed layer to become the conductive blind holes 314. The first outer wiring layer 410 and the second outer wiring layer 420 electrical connect with each other through the conductive via 313. The second outer wiring layer 420 and the second wiring layer 112 electrical connect with each other through conductive blind holes 314.

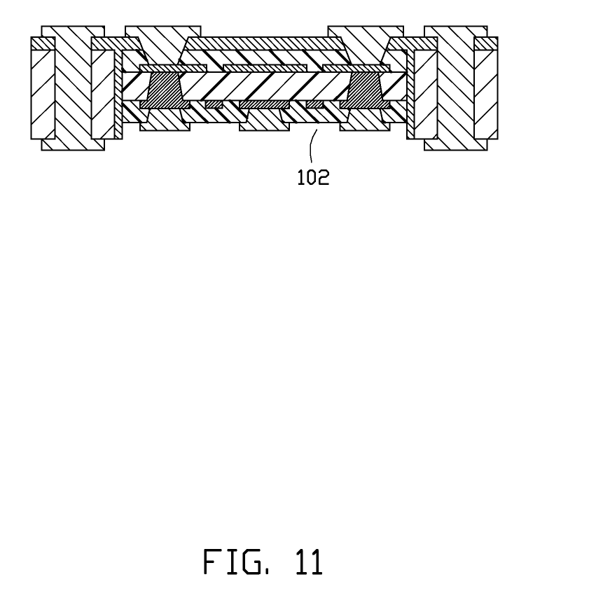

FIG. 11 shows the step of eliminating the protective layer 13 in the illustrated embodiment the protective layer 13 is removed by film stripping, then forming a receiving cavity 102.

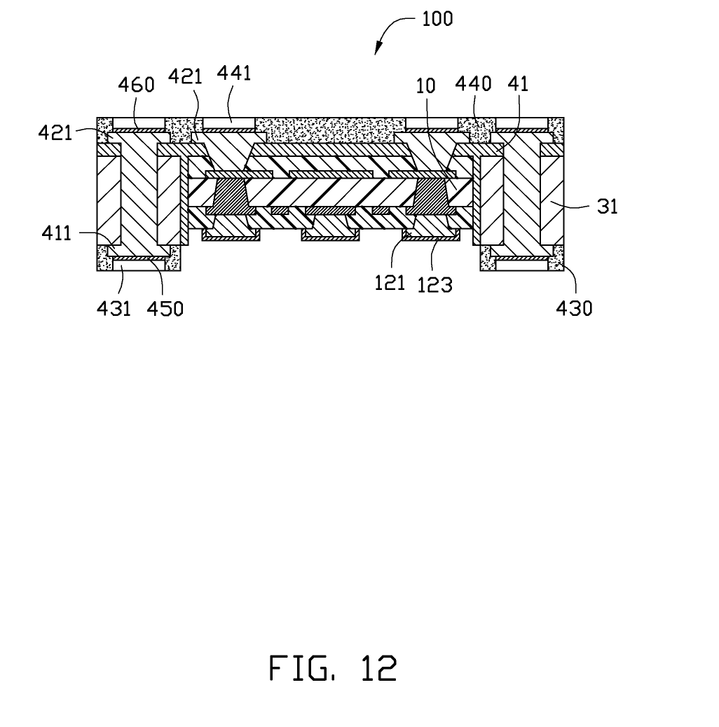

FIG. 12 show: forming a first solder resist layer 430 on the surface of the first outer wiring layer 410 and the surface of the first insulating layer 31, which is exposed via the first outer wiring layer 410. Then, forming a second solder resist layer 440 on the surface of the second outer wiring layer 420 and the surface of the first dielectric sheet 41 which is exposed via the second outer wiring layer 420. The first solder resist layer 430 has a plurality of first openings 431 corresponding to a plurality of second contact pads 411, each second contact pad 411 is exposed via the corresponding first opening 431. The second solder resist layer 440 has a plurality of second openings 441 corresponding to a plurality of third contact pads, each third contact pad is exposed via the corresponding second opening 441.

Then, forming a first protective layer 123 on the surface of each first contact pad 121 of the first wiring layer 12, forming a second protective layer 450 on the surface of each second contact pad 411 which is exposed via the first opening 431. Forming a third protective layer 460 on the surface of each third protective layer 430 which is exposed via the second openings 441. Therefore, obtain a circuit board 100.

In the illustrated embodiment, the first protective layer 123, the second protective layer 450 and the third protective layer 460 are a single layer of tin. In other embodiments, the protective layers 123, 450, 460 may be materials such as lead, silver, gold, nickel, palladium or an alloy thereof, or can be a multilayer of two or more of the above-mentioned metals. The first protective layer 123, the second protective layer 450 and the third protective layer 460 can be organic solderable preservatives. When the first protective layer 123, the second protective layer 450, and the third protective layer 460 are metal, the protective layers 123, 450, 460 can be formed by electroless plating. When the protective layers 123, 450, 460 are organic solderable preservatives, a chemical method is used to form the protective layers 123, 450, 460.

FIGS. 3 and 4 show that in other embodiments, the core substrate, the insulating layer and the dielectric sheet can be set on one side of the carrier.

In the embodiment, because the protective layer 13 can be eliminated, the circuit board 100 has a receiving cavity 102, the first contact pad 121 can be exposed via the receiving cavity 102.

FIG. 12 shows a circuit board 100 is provided by the manufacturing method of present disclosure. The manufacturing method comprises a core substrate 10, a first insulating layer 31, a first dielectric sheet 41, a first outer wiring layer 410 and a second outer wiring layer 420.

The first insulating layer 31 comprises a first opening 33 corresponding to the core substrate 10, the cross-section area of the first opening 33 is larger than the cross-section area of the core substrate 10. The core substrate 10 is received in the first opening 33. The first dielectric sheet 41 connects one side surface of the core substrate 10 and the first insulating layer 31. The first dielectric 41 is formed in the first opening 33 to fill the gap between the first insulating layer 31 and the core substrate 10, therefore, making the first insulating layer 31, the core substrate 10 and the first dielectric sheet 41 become a unit.

The first outer wiring layer 410 is formed on the surface of the first insulating layer 31 away from the first dielectric sheet 41. The second outer wiring layer 420 is formed on the surface of the first dielectric sheet 41. Defining at least one conductive via 313 in the first insulating layer 31, the first outer wiring layer 410 electrical connects with the second outer wiring layer 420 through the conductive via 313.

The thickness of the first insulating layer 31 is larger then the thickness of the core substrate 10. On one side of the first outer wiring layer 410, the circuit board 100 has a receiving cavity 102. The first wiring layer 12 of the core substrate 10 is exposed via the receiving cavity 102.

The first wiring layer 12 comprises a plurality of first contact pads 121. The first outer wiring layer 410 comprises a plurality of second contact pads 411. The second outer wiring layer 420 comprises a plurality of third contact pads.

The circuit board 100 further comprises a first solder resist layer 430 and a second solder resist layer 440. The first solder resist layer 430 has a plurality of first openings 431 corresponding to a plurality of second contact pads 411, and each second contact pad 411 is exposed via the first opening 431. The second solder resist layer 440 has a plurality of second openings 441 corresponding to a plurality of third contact pads, and each third contact pad is exposed via the second openings 441.

The circuit board 100 further comprises first protective layers 123, second protective layers 450 and third protective layers 460. The first protective layers 123 are formed on the surface of each first contact pad 121 of the first wiring layer 12. The second protective layers 450 are formed on the surface of each second contact pad 411 which are exposed via the first opening 431. The third protective layers 460 are formed on the surface of each third contact pad, which is exposed via the second, opening 441.

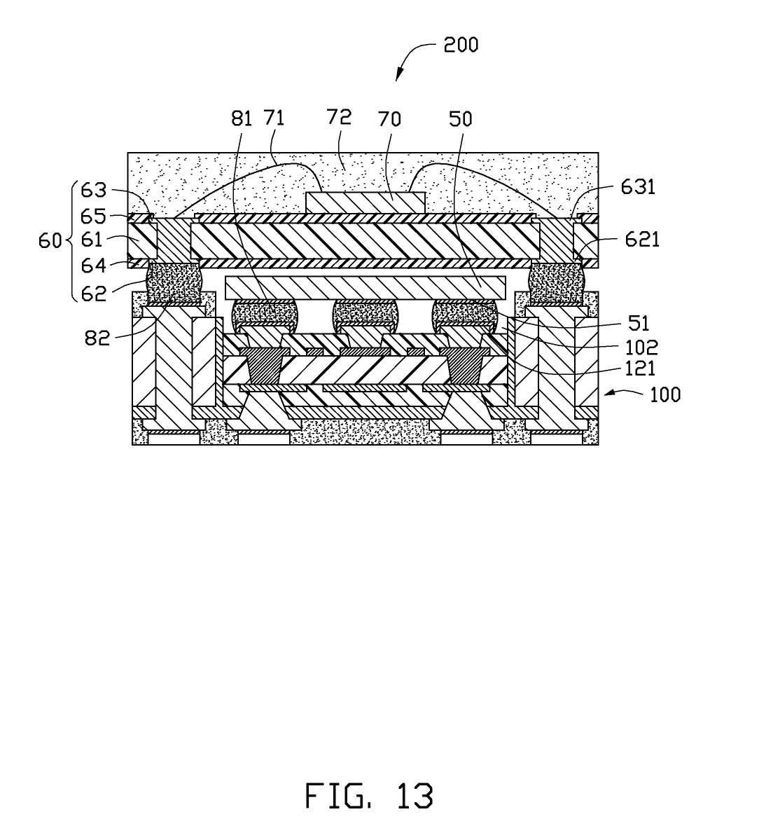

FIG. 13 shows a package structure 200 of the circuit board, which is provide by present disclosure.

The package structure 200 comprises a circuit board 100, a first chip 50, a connecting substrate 60 and a second chip 70.

The first chip 50 is packaged on the circuit board 100. The cross-section area of the first chip 50 is equal to the cross-section area of the receiving cavity 102. The first chip 50 has a plurality of fourth contact pads 51 corresponding to the first contact pads 121. Bach first contact pad contacts each corresponding fourth contact pad through a first solder ball 81. The material of the first solder ball 81 can be tin, lead, copper or an alloy thereof. Because the circuit board has the receiving cavity 102, the first solder balls 81 can be received in the receiving cavity 102, or part of or all of the first chip 50 can be received in the receiving cavity 102.

The connecting substrate 60 comprises an insulating base 61, at least one first conductive pattern 62 and second conductive pattern 63 positioned on the opposite sides of the insulating base 61. A third solder resist layer 64 is positioned on the first conductive pattern 62 and a fourth solder resist layer 65 is positioned on the second conductive pattern 63. At least one conductive via is defined in the insulating base 61, and the first conductive pattern 62 electrically connects to the second conductive pattern 63 through the conductive via. The first conductive pattern 62 has a plurality of fifth contact pads 621 corresponding to a plurality of second contact pads 411. The second conductive pattern 63 has a plurality of sixth contact pads 631.

The third solder resist layer 64 has a plurality of third openings, each the fifth contact pad 621 is exposed via the third openings. A plurality of fourth openings are defined in the fourth solder resist layer 65, and each sixth contact pads 631 is exposed via the fourth opening.

The connecting base 60 is packaged on the circuit board 100. In the illustrated embodiment, each fifth contact pad 621 electrically connects with corresponding second contact pad 411 through the second solder ball.

The second chip 70 is packaged on the connecting base 60. In the embodiment, the second chip 70 is a wire-bonding chip, and the second chip 70 electrically connects with the sixth electrical connection pads 631. The second chip 70 has a plurality of wire-bonding sites and a plurality of wire-bonding lines 71 extends from the wire-bonding site, and the wire-bonding line 71 corresponding to the sixth contact pads 631. One end of a plurality of the wire-bonding line electrical connects the second chip 70, and the other end of a plurality of the wire-bonding line electrical connects the sixth contact pad 631, therefore, the second chip 70 electrical connects with the second conductive pattern 63.

In the embodiment, the wire-bonding line 71, the second chip 70, the third solder resist layer 64 and the sixth contact pad 631 are package by a encapsulant 72. In the embodiment, the encapsulant 72 is black gel; however, the encapsulation gel can be other encapsulation gel material.

The circuit board and the manufacturing method of the circuit board provided by present disclosure provides a core substrate with first conductive patterns and a insulating base with openings, then connects the core substrate and the insulating base with dielectric sheet, then forms the outer wiring layer. The conductive wire in the core substrate and the outer conductive wire are manufactured separately, therefore, the conductive wire in the core substrate can use thin wire, and the outer conductive wire can use thick wire. The forming of thin wire on the area, which does not require the thin wire can be achieved. In other words, it can reduce the complexity of manufacturing of circuit board, and reduce the cost of manufacturing of circuit board.

During the processes of manufacturing, the thickness of the insulating layer is larger then the thickness of the core substrate, the core substrate is received in the opening of the insulating layer to become a receiving cavity. When packaging the circuit board, the chip can be partially or complete received in the receiving cavity, the size of the package of the package structure can be reduced.

The above-mentioned embodiments of the present disclosure are intended to be illustrative only. Persons skilled in the art may devise numerous alternative embodiments without departing from the scope of the following claims.

What is claimed is:

1. A method for manufacturing a circuit board, comprising steps of:
providing a core substrate which comprises a circuit base, a first wiring layer and a protective layer, the protective layer formed on a surface of the first wiring layer, the first wiring layer comprising a plurality of first contact pads;
providing a carrier and an insulating layer, the insulating layer having an opening having a shape conforming to the shape of the core substrate, the area of cross-section of the opening is larger than the area of cross-section of the core substrate;
positioning the core substrate and the insulating layer on a same side of the carrier, and making the protective layer in contact with the carrier, wherein the core substrate is received in the opening;
attaching a dielectric sheet on a side of the combined core substrate and insulating layer to force a part of the dielectric sheet into the opening to connect the core substrate with the insulating layer, thereby the dielectric sheet, the core substrate and the insulating layer cooperatively constituting a semifinished board;
separating the semifinished board form the carrier;
forming two outer wiring layers on the dielectric sheet, the outer wiring layer comprising a plurality of second contact pads; and
removing the protective layer to form a receiving cavity and expose the first contact pads from the receiving cavity, thereby obtaining a circuit board, which the width/space of the first wiring layer is smaller than the width/space of the outer wiring layers.

2. The method as claimed in claim 1, wherein in the step of forming the two outer wiring layers, a conductive via is defined in the dielectric sheet and the insulating layer, the two outer wiring layers are electrically connected with each other through the conductive via.

3. The method as claimed in claim 1, wherein in the step of forming the two outer wiring layers, further comprising defining at least one conductive blind hole to electrically connect the conductive layer of the core substrate and one of the two outer wiring layer.

4. The method as claimed in claim 1, wherein the thickness of the insulating layer is larger than the thickness of the core substrate.

5. The method as claimed in claim 1, further comprising: forming protective layers on the surfaces of the first contact pad and the second contact pad.

6. The method as claimed in claim 1, wherein a release film is formed on the surface of the carrier.

7. A circuit board, comprising;
a core substrate;
an insulating layer;
a dielectric sheet;
a first outer wiring layer; and
a second outer wiring layer;
wherein the insulating layer comprises at least one first opening corresponding to the core substrate, the area of cross-section of the first opening is larger than the area of cross-section of the core substrate, the core substrate is received in the opening, the dielectric sheet connects one side surface of the core substrate and the insulating layer and forced Into the opening to fill a gap between the insulating layer and core substrate, the first outer wiring layer is formed on the surface of insulating layer, the second outer wiring layer is formed on the surface of the dielectric sheet, the first contact pad is exposed.

8. The circuit board as claimed is claim 7, wherein a conductive via is defined in the insulating layer and the dielectric sheet void, and the first outer wiring layer and the second outer wiring layer are electrically connected to each other through the conductive via.

9. The circuit board as claimed in claim 7, wherein the thickness of the insulating layer is larger than the thickness of the core substrate.

10. The circuit board as claimed in claim 7, wherein a protective layer is formed on the surface of the first contact pad.

11. A package structure comprises: a first chip and a circuit board as claimed in claim 7, wherein the first chip electrical connects with first contact pad through a first solder ball.

12. The package structure as claimed in claim 11, further comprising: a connecting substrate and a second chip, the second chip is packaged on the connecting substrate, the connecting substrate connects the second wiring layer with a second solder ball.
